(19) United States
(12) Patent Application Publication
(10) Pub. No.: US 2026/0112881 A1
(43) Pub. Date: Apr. 23, 2026

(54) COMPLEX FAULT PROTECTION METHOD AND SYSTEM FOR SINGLE RETURN LINE OF ARC SUPPRESSION COIL GROUND SYSTEM

(71) Applicant: GUANGZHOU POWER SUPPY BUREAU OF GUANGDONG POWER GRID CO., LTD., Guangzhou, Guangdong (CN)

(72) Inventors: Qilin Zhou, Guangzhou, Guangdong (CN); Rui Tong, Guangzhou, Guangdong (CN); Zhiyong Liu, Guangzhou, Guangdong (CN); Jie Han, Guangzhou, Guangdong (CN); Minghao Liu, Guangzhou, Guangdong (CN); Xiaofeng Dai, Guangzhou, Guangdong (CN); Guanwu Qiu, Guangzhou, Guangdong (CN); Guokai Liang, Guangzhou, Guangdong (CN); Qinming Liu, Guangzhou, Guangdong (CN); Yuchang Ling, Guangzhou, Guangdong (CN)

(21) Appl. No.: 18/859,944

(22) PCT Filed: Aug. 28, 2023
(86) PCT No.: PCT/CN2023/115313

§ 371 Date: Jul. 3, 2025

(30) Foreign Application Priority Data
Nov. 12, 2022 (CN) 202211416449.7

(51) Int. Cl. H02H 3/38; G01R 31/08; H02H 1/00; H02H 3/16; H02H 7/26

(52) U.S. Cl. CPC H02H 3/382; G01R 31/088; H02H 1/0092; H02H 3/16; H02H 7/26

(57) ABSTRACT

The present disclosure discloses a complex fault protection method and system for a single return line of an arc suppression coil ground system. The method determines whether a ground fault occurs in the corresponding line based on a negative sequence measurement impedance angle or a negative sequence measurement admittance angle of the line in the arc suppression coil ground system. The system is used to implement the above method. The complex fault protection method of the present disclosure can provide protection for the complex fault situation where two points in a single return line are grounded out of phase and is not affected by factors such as the fault position and the transition resistance. Furthermore, the complex fault protection method also has a strong anti-interference ability and a high stability, applicability and sensitivity.

### FIELD

The present disclosure relates to the field of power network fault protection technology, and more particularly to a complex fault protection method and system for a single return line of an arc suppression coil ground system.

### BACKGROUND

With the continuous increase in electricity demand, the structure of the power network is becoming increasingly complex and large, and the requirement for the power supply reliability correspondingly increases. The frequent faults in distribution lines are single-phase ground faults, which can develop into other complex faults. Therefore, in order to ensure the safe operation of the power system, appropriate ground protection needs to be provided. Under extreme conditions such as typhoons, the power network may experience multiple single-phase ground faults at the same time, and there are many types of single-phase ground faults, thus, a simple ground protection method is not applicable.

An arc suppression coil ground system is a compensation device used in a low current ground system. When a single-phase ground fault occurs in the power network, an arc suppression coil generates an inductive current to compensate for a ground capacitance current, such that the current passing through the ground point is lower than the current required to generate intermittent arcs or maintain stable arcs, thus eliminating the arc at the ground point.

The arc suppression coil ground system usually includes a bus bar and multiple return lines connected to the bus bar. An accurate positioning of a faulty return line is the key to the fault protection of the arc suppression coil ground system. In the existing technology, a zero sequence current method is usually used to determine the faulty return line, which is based on a difference between a transient zero sequence current direction of the faulty line and that of a non-faulty line, such that the faulty line can be determined. This method is designed for situations where two different return lines have in-phase ground faults and is not applicable to situations where two points of the same return line are grounded out of phase.

Another method is to use a single-phase ground simple fault zero sequence over-current protection. This protection method can effectively act on the section of the line between two faulty points on the same return line. However, for the section of the line between the first faulty point and the bus bar, due to the small zero sequence current in this section, there is a risk of “refuse-operation of the protection”.

In addition, a zero sequence voltage of the bus bar and a zero sequence voltage of each return line are collected in real time, amplitudes and phases of the two zero sequence voltages are compared to select the line with two consecutive ground faults. However, this method can be only applicable to selecting the ground faults at two points on different return lines, and has a low sensitivity.

In summary, there is currently no effective fault protection method in the existing technology for the situation of multiple faults in the same return line of the arc suppression coil ground system, where two points are grounded out of phase, and rapid faulty line selection and protection cannot be achieved.

### SUMMARY

In order to solve the problems in the existing technology mentioned above, the purpose of the present disclosure is to provide a complex fault protection method and system for a single return line of an arc suppression coil ground system. The complex fault protection method can provide protection for the complex fault situations where two points in a single return lines are grounded out of phase and is not affected by factors such as the fault position and the transition resistance. Furthermore, the complex fault protection method has a strong anti-interference ability and a high stability, applicability and sensitivity.

The complex fault protection method for a single return line of an arc suppression coil ground system provided in the present disclosure determines whether a ground fault occurs in the corresponding line based on a negative sequence measurement impedance angle or a negative sequence measurement admittance angle of the line in the arc suppression coil ground system.

In an embodiment, the complex fault protection method further includes the following steps:
obtaining a negative sequence impedance angle of each line when the arc suppression coil ground system is in normal operation, wherein the negative sequence impedance angle is marked as θₛₑₜ;
obtaining the negative sequence measurement impedance angle θₖ of a line potentially having a ground fault;
calculating an impedance angle difference between the negative sequence measurement impedance angle θₖ and the normal negative sequence impedance angle θₛₑₜ, wherein the impedance angle difference is marked as Δθ;
determining whether the impedance angle difference Δθ is in a preset impedance angle difference interval, when the impedance angle difference Δθ is in the preset impedance angle difference interval, it is determined that the line has a ground fault, otherwise, it is determined that the line has no ground faults; or,
obtaining a negative sequence admittance angle of each line when the arc suppression coil ground system is in normal operation, wherein the normal negative sequence admittance angle is marked as φₛₑₜ;
obtaining the negative sequence measurement admittance angle φₖ of the line potentially having a ground fault;
calculating an admittance angle difference between the negative sequence measurement admittance angle φₖ and the normal negative sequence admittance angle φₛₑₜ, wherein the admittance angle difference is marked as Δφ;
determining whether the admittance angle difference Δφ is in a preset admittance angle difference interval; when the admittance angle difference Δφ is in the preset admittance angle difference interval, it is determined that the line has a ground fault; otherwise, it is determined that the line no ground faults.

In an embodiment, the line potentially having a ground fault is determined by the following steps:
obtaining a negative sequence current setting value İₛₑₜ of the arc suppression coil ground system;
obtaining a beginning-end negative sequence current İ_{L(2)} of each line; and
determining whether the beginning-end negative sequence current İ_{L(2)} is greater than the negative sequence current setting value İₛₑₜ; when the beginning-end negative sequence current İ_{L(2)} is greater than the negative sequence current setting value İₛₑₜ, it is determined that the line potentially has a ground fault; otherwise, it is determined that the line operates normally.

In an embodiment, the negative sequence measurement impedance angle θₖ of the line potentially having a ground fault is calculated according to the following steps:
obtaining a negative sequence voltage \dot{U}_{L(2)} of the line potentially having a ground fault;
calculating the negative sequence measurement impedance angle θₖ according to the following formula:

$${θ}_{k} = arg \frac{{\dot{U}}_{L ( 2 )}}{{\dot{I}}_{L ( 2 )}} ;$$

calculating the negative sequence measurement admittance angle φₖ of the line potentially having a ground fault according to the following steps:
obtaining the negative sequence voltage \dot{U}_{L(2)} of the line potentially having a ground fault; and
calculating the negative sequence measurement admittance angle φₖ according to the following formula:

$${φ}_{k} = - arg \frac{{\dot{U}}_{L ( 2 )}}{{\dot{I}}_{L ( 2 )}} .$$

In an embodiment, the negative sequence current setting value is calculated according to the following formula:

$${\dot{I}}_{set} = {k}_{k} \vert {\dot{I}}_{k ( 2 )} \vert ;$$

wherein, kₖ represents a reliability coefficient and İₖ₍₂₎ represents the negative sequence current generated on the faulty line when other feeders have single-phase ground faults.

In an embodiment, the impedance angle difference interval C_{θ}=[−180° −90° ], and the admittance angle difference interval C_{φ}=[90° , 180° ].

The present disclosure further provides a complex fault protection system for a single return line of an arc suppression coil ground system, including:
an acquisition module configured to obtain a negative sequence measurement impedance angle or a negative sequence measurement admittance angle of a line in the arc suppression coil ground system; and
a judgment module configured to determine whether a ground fault occurs in a corresponding line according to the negative sequence measurement impedance angle or negative sequence measurement admittance angle.

The present disclosure further provides a computer device including a processor and a memory in signal connection with the processor, wherein the memory stores at least one instruction or at least one program which, when being loaded by the processor, implements above the complex fault protection method for a single return line of an arc suppression coil ground system.

The present disclosure further provides a computer-readable storage medium storing at least one instruction or at least one program, wherein when the at least one instruction or the at least one program is loaded by a processor, the above complex fault protection method for a single return line of an arc suppression coil ground system is implemented.

The complex fault protection method and system for a single return line of an arc suppression coil ground system provided in the present disclosure can calculate the negative sequence measurement impedance or the negative sequence measurement admittance by obtaining the negative sequence current and the beginning-end negative sequence voltage of the line, and then obtain the negative sequence measurement impedance angle or the negative sequence measurement admittance angle which can be used to identify and judge the faulty line and form protection. The complex fault protection method of the present disclosure can provide protection for complex fault situations where two points in a single return line are grounded out of phase, and only requires the negative sequence information of the line to identify the faulty line; moreover, the information acquisition and communication volume are small, and the requirements for equipment synchronization are low, thus, the method can be easily applied. At the same time, the method can respond to the change of the two-point ground position, and is not affected by factors such as the fault position and the transition resistance. Furthermore, the method can also be effectively applied when two phases are grounded at the same point, and has a strong anti-interference ability and a high stability, applicability, and sensitivity.

### BRIEF DESCRIPTION OF THE DRAWINGS

To describe the technical solutions in the embodiments of the present disclosure more clearly, the following briefly introduces the accompanying drawings required for describing the embodiments or the prior art. Apparently, the accompanying drawings in the following description show merely some embodiments of the present disclosure, and persons of ordinary skill in the art may still derive other drawings from these accompanying drawings without creative efforts.

FIG. 1 is a flowchart of a judgment process for a complex fault protection method for a single return line of an arc suppression coil ground system according to an embodiment of the present disclosure;

FIG. 2 is a schematic diagram showing a complex two-point ground fault in the arc suppression coil ground system according to an embodiment of the present disclosure;

FIG. 3 is a negative sequence network diagram of the complex two-point ground fault corresponding to FIG. 1;

FIG. 4 is diagram showing a distribution of a negative sequence measurement impedance angle according to an embodiment of the present disclosure;

FIG. 5 is a schematic diagram of a distribution network simulation model according to an embodiment of the present disclosure; and

FIG. 6 is a schematic diagram of a computer device according to an embodiment of the present disclosure.

### DESCRIPTION OF REFERENCE NUMERALS

T0, ground transformer,
T1, main transformer,
101, processor, and
102, memory.

### DETAILED DESCRIPTION

In order to make the objectives, features, and advantages of the present disclosure more obvious and understandable, the technical solutions in the embodiments of the present disclosure will be clearly and completely described below in conjunction with the accompanying drawings of the embodiments of the present disclosure. It is apparent that the embodiments described below are only a part of the embodiments of the present disclosure, not all of them. Based on the embodiments of the present disclosure, all other embodiments obtained by those skilled in the art without creative effort fall within the scope of protection of the present disclosure.

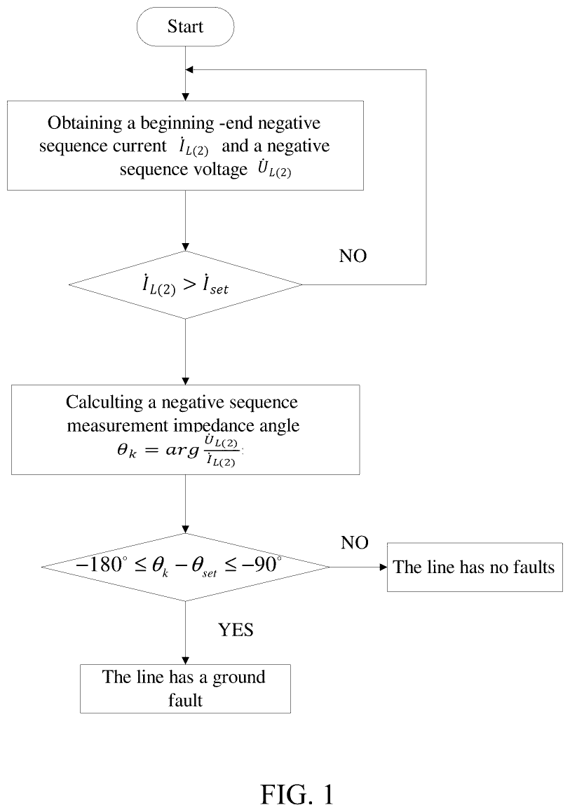

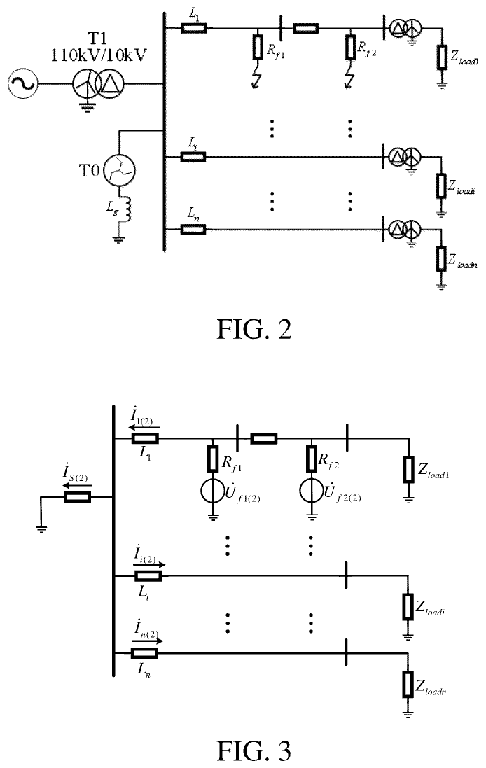

As shown in FIG. 1, a complex fault protection for a single return line of an arc suppression coil ground system disclosed in the present disclosure determines whether a ground fault occurs in a corresponding line according to a negative sequence measurement impedance angle or a negative sequence measurement admittance angle of the line in the arc suppression coil ground system. That is, there is a significant difference between the negative sequence measurement impedance angle of a faulty line and the negative sequence measurement impedance angle of a non-faulty line (hereinafter as “normal line”). The principle is as follows: for a 10 KV arc suppression coil ground system shown in FIG. 2, TO is a ground transformer, T1 is a main transformer on the system side, Lᵢ(i=1,2 . . . n) represents a length of each feeder line; when two points in a feeder line L₁ are simultaneously grounded out of phase, a faulty point f₁ is grounded at a B phase, a faulty point F₂ is grounded at a C phase, R_{f1} is a ground transition resistance of the faulty point f₁, R_{f2} is a ground transition resistance of the faulty point f₂, L_{f1} is a distance between a bus bar and the faulty point f₁, L_{f2} is a distance between the bus bar and the faulty point f₂, Z_{loadi}(i=1, 2, . . . n) is a load of a i_th feeder line, and the negative sequence network is used for analysis as shown in FIG. 2.

FIG. 3 shows the negative sequence network of the two-phase ground complex fault in the single return line of the arc suppression coil ground system of FIG. 2. Taking the negative sequence measurement impedance angle as an example, \dot{U}_{f1} and \dot{U}_{f2} in FIG. 3 are equivalent power sources of the negative sequence network, which are calculated as follows:

$$\begin{matrix}{\dot{U}}_{f 1 ( 2 )} = \frac{{rY}_{2 ( 2 )} {\dot{I}}_{f 1 ( 0 )} + {Y}_{12 ( 2 )} {\dot{I}}_{f 2 ( 0 )}}{{r}^{2} ( {Y}_{12 ( 2 )}^{2} - {Y}_{1 ( 2 )} {Y}_{2 ( 2 )} )} ; \\ {\dot{U}}_{f 2 ( 2 )} = \frac{{Y}_{1 ( 2 )} {\dot{I}}_{f 2 ( 0 )} + {rY}_{12 ( 2 )} {\dot{I}}_{f 1 ( 0 )}}{{r}^{2} ( {Y}_{12 ( 2 )}^{2} - {Y}_{1 ( 2 )} {Y}_{2 ( 2 )} )} ;\end{matrix}$$

Wherein, İ_{f1(0)} and İ_{f2(0)} are respectively zero sequence currents at the faulty points f₁ and f₂, which can be obtained by solving a composite sequence network diagram; Y₁₍₂₎, Y₂₍₂₎ and Y₁₂₍₂₎ are respectively a self-admittance of the faulty point f₁, a self-admittance of the faulty point f₂, and a mutual admittance between the two faulty points f₁ and f₂ of the negative sequence network. Thus, a negative sequence voltage and a beginning-end negative sequence current of the faulty line can be obtained. The negative sequence voltage of the bus bar is:

$${\dot{U}}_{L ( 2 )} = {\dot{U}}_{f 1 ( 2 )} ( 1 - {𝓏}_{2} {l}_{1 - 1} {Y}_{d 1 ( 2 )} + \frac{j ω {c}_{2} {𝓏}_{2} {l}_{1 - 1}^{2}}{2} ) ∘$$

Wherein, z₂ is a negative sequence impedance per unit line length, l₁₋₁ is a distance between the bus bar and a first faulty point, Y_{d1(2)} is a total negative sequence admittance from point to ground, c₂ is a negative sequence capacitance per unit line-to-ground length, and ω an angular frequency.

The beginning-end negative sequence current of the faulty line is:

$${\dot{I}}_{L 1 ( 2 )} = {\dot{U}}_{f 1 ( 2 )} ( j ω {c}_{2} {l}_{1 - 1} - {Y}_{d 1 ( 2 )} - \frac{{ω}^{2} {c}_{2}^{2} {𝓏}_{2} {l}_{1 - 1}^{3}}{4} - \frac{j ω {c}_{2} {𝓏}_{2} {l}_{1 - 1}^{2} {Y}_{d 1 ( 2 )}}{2} ) ;$$

The beginning-end negative sequence current of the i-th normal line is:

$${\dot{I}}_{L i ( 2 )} = \frac{{\dot{U}}_{L ( 2 )} [ 4 - {ω}^{2} {c}_{2}^{2} {𝓏}_{2} {Z}_{loadi ( 2 )} {l}_{i}^{3} + 2 j ω {c}_{2} {l}_{i} ( {𝓏}_{2} {l}_{i} + 2 {Z}_{loadi ( 2 )} ) ]}{2 ( 2 {Z}_{loadi ( 2 )} + 2 {𝓏}_{2} {l}_{i} + j ω {c}_{2} {𝓏}_{2} {Z}_{loadi ( 2 )} {l}_{i}^{2} )} ;$$

The negative sequence measurement impedance of each line can be obtained when a two-phase ground fault occurs in a single return line through the negative sequence voltage and the beginning-end negative sequence current of the line. The negative sequence measurement impedance of the faulty line is:

$${Z}_{cL 1 ( 2 )} = \frac{{\dot{U}}_{L ( 2 )}}{{\dot{I}}_{L 1 ( 2 )}} = \frac{4 - 4 {𝓏}_{2} {l}_{1 - 1} {Y}_{d 1 ( 2 )} + 2 j ω {c}_{2} {𝓏}_{2} {l}_{1 - 1}^{2}}{4 j ω {c}_{2} {l}_{1 - 1} - 4 {Y}_{d 1 ( 2 )} - {ω}^{2} {c}_{2}^{2} {𝓏}_{2} {l}_{1 - 1}^{3} - 2 j ω {c}_{2} {𝓏}_{2} {l}_{1 - 1}^{2} {Y}_{d 1 ( 2 )}} ;$$

For the normal line, the measurement impedance is:

$${Z}_{cLi ( 2 )} = \frac{4 - {ω}^{2} {c}_{2}^{2} {𝓏}_{2} {Z}_{loadi ( 2 )} {l}_{i}^{3} + 2 j ω {c}_{2} {l}_{i} ( {𝓏}_{2} {l}_{i} + 2 {Z}_{loadi ( 2 )} )}{2 ( 2 {Z}_{loadi ( 2 )} + 2 {𝓏}_{2} {l}_{i} + j ω {c}_{2} {𝓏}_{2} {Z}_{loadi ( 2 )} {l}_{i}^{2} )} ;$$

Wherein, lᵢ is a length of the i-th normal line.

For the normal line, the negative sequence measurement impedance is a sum of a line impedance and a load impedance. Since the negative sequence impedance of the line is relatively small compared to the load impedance, the negative sequence impedance can be ignored. Therefore, it can be considered that the negative sequence measurement impedance is the load impedance, and the load is generally weakly inductive, with a phase between about 00 and 45°.

For the faulty line, the negative sequence measurement impedance approximates a system negative sequence impedance. The system negative sequence impedance is mainly an equivalent impedance of the main transformer, which is strongly inductive and has a phase of about 90°. However, since a direction of flow from the bus bar is specified as a positive direction, the phase of the measurement impedance of the faulty line is −90°.

Considering a certain margin, the negative sequence measurement impedance angle of the faulty line can be −90±5, that is:

$$arg {Z}_{cL 1 ( 2 )} ∈ ( - 85 ° , - 95 ° ) ;$$

For the normal line, the negative sequence measurement impedance angle is:

$$arg {Z}_{cLi ( 2 )} ∈ ( 0 ° , 45 ° ) ∘ .$$

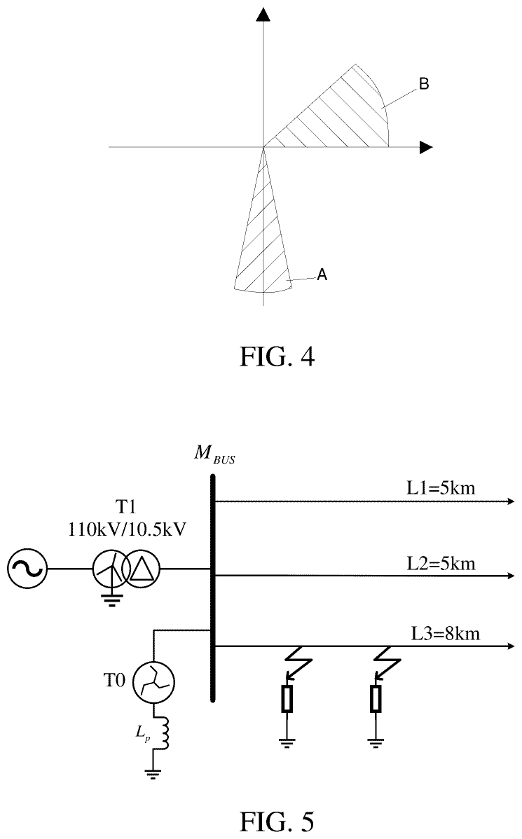

The distributions of the negative sequence measurement impedance angles of the faulty line and the normal line is shown in FIG. 4. It can be seen that for the faulty line with a ground fault, the negative sequence measurement impedance angle is significantly different from that of the normal line. Therefore, the negative sequence measurement impedance angle of each line can be used to determine whether the corresponding line has a ground fault. Also, for a normal line, the relationship between the negative sequence measurement admittance angle and the negative sequence measurement impedance angle is stable, and the negative sequence measurement admittance angle is equal to the minus negative sequence measurement impedance angle; thus, when the relationship between the negative sequence measurement admittance angle and the negative sequence measurement impedance angle is changed or the negative sequence measurement admittance angle is not equal to the minus negative sequence measurement impedance angle, it is determined that the line may be a faulty line. Such determining process can be understood by referring to the content of negative sequence measurement impedance angle and is not repeated hereinafter.

As shown in detail in FIG. 1, the complex fault protection method for a single return line of an arc suppression coil ground system includes steps as follows.

Taking the negative sequence measurement impedance angle as an example, at first two reference values, namely a negative sequence current setting value İₛₑₜ and a normal sequence impedance angle of the arc suppression coil ground system are obtained. The negative sequence current setting value İₛₑₜ is calculated according to the following formula:

$${\dot{I}}_{set} = {k}_{k} \vert {\dot{I}}_{k ( 2 )} \vert ;$$

wherein, kₖ represents a reliability coefficient and İₖ₍₂₎ represents the negative sequence current generated in the faulty line when another feeder line has a single-phase ground fault.

The normal negative sequence impedance angle θₛₑₜ represents the negative sequence impedance angle of each line when the system is in normal operation. The calculation formula of the normal negative sequence impedance angle θₛₑₜ can refer to the negative sequence measurement impedance angle of the normal line, and the negative sequence measurement impedance angle of the normal line when the system is in normal operation is used as the normal negative sequence impedance angle θₛₑₜ.

When the complex fault protection method for a single return line of an arc suppression coil ground system is implemented, the negative sequence information of each line, namely the negative sequence current İ_{L(2)} and the beginning-end negative sequence voltage \dot{U}_{L(2)} of each line are obtained.

The beginning-end negative sequence current İ_{L(2)} is compared with the negative sequence current setting value İₛₑₜ mentioned above to determine whether the beginning-end negative sequence current İ_{L(2)} is greater than the negative sequence current setting value İₛₑₜ. If the beginning-end negative sequence current i_{L(2)} is greater than the negative sequence current setting value İₛₑₜ, it is determined that the corresponding line potentially has a ground fault. Otherwise, it is determined that the line operates normally.

For the line which is determine to potentially have the ground fault, further judgment is carried out. The negative sequence measurement impedance angle θₖ of the line potentially having a ground fault is calculated, and the difference between the negative sequence measurement impedance angle θₖ and the normal negative sequence impedance angle θₛₑₜ is calculated to obtain an impedance angle difference, which is marked as Δθ.

Whether the impedance angle difference Δθ is in a preset impedance angle difference interval C_{θ} or not is determined. That is, whether the difference between the negative sequence measurement impedance angle θₖ and the normal negative sequence impedance angle θₛₑₜ meets certain numerical conditions or not is determined. If yes, it is determined that the line has a ground fault. Otherwise, it is determined that the line has no ground faults.

In an embodiment, the impedance angle difference interval C_{θ} is designed by referring to the phase ranges of the negative sequence measurement impedance angles of the faulty line and the normal line mentioned above. In order to ensure the effectiveness of fault protection and avoid omissions, the impedance angle difference interval C_{θ} should be greater than a phase difference range of the negative sequence measurement impedance angles of the faulty lines and the normal lines, thus, the impedance angle difference interval is designed to be C_{θ}=[−180°, −90° ]. Therefore, the impedance angle difference interval can effectively include the phase difference range of the negative sequence measurement impedance angles of the faulty line and the normal lines, thereby providing effective fault protection.

When the negative sequence measurement impedance angle θₖ of a line potentially having aground fault satisfies the relationship −180°≤θₖ−θₛₑₜ≤−90°, it is determined that the line has a ground fault. Otherwise, it is determined that the line has no faults.

Correspondingly, the formula for calculating the negative sequence measurement admittance angle φₖ is as follows:

$${φ}_{k} = - arg \frac{{\dot{U}}_{L ( 2 )}}{{\dot{I}}_{L ( 2 )}} .$$

Then, an admittance angle difference interval is designed to be C_{φ}=[90°, 180° ], which has the same principle as the negative sequence measurement impedance angle θₖ and can be understood by referring to the previous description, which is not repeated hereinafter.

The following further illustrates the technical effect of the complex fault protection method for a single return line of an arc suppression coil ground system described in this embodiment through simulation examples.

As shown in FIG. 5, a simulation model of the 10 KV arc suppression coil ground system is built using PSCAD. Three lines are set up, including a line L1 with a length of 5 km, a line L2 with a length of 5 km, and a line L3 with a length of 8 km. Positive sequence parameters of the line are as follows:

$$\begin{matrix}{𝓏}_{1} = ( 0.105 + j 0.08 ) Ω / km ; \\ {c}_{1} = 0.12 μF / km ;\end{matrix}$$

Zero sequence parameters of the line are as follows:

$$\begin{matrix}{𝓏}_{0} = ( 1.05 + j 5.027 ) Ω / km ; \\ {c}_{0} = 6.4 \times {10}^{- 3} μF / km ; \\ {L}_{p} = 0.417 H .\end{matrix}$$

Assuming a single-phase disconnection fault occurs in the line L3, a method such as a zero sequence current method is used at first to verify and determine the fault state of the line L3 as follows.

The beginning-end zero sequence current İ₍₀₎ of each line and the zero sequence voltage \dot{U}₍₀₎ of the bus bar are obtained, a ratio of the zero sequence current İ⁽⁰⁾ to the zero sequence voltage \dot{U}₍₀₎ of each line is calculated to obtain a zero sequence admittance component Yᵢ₍₀₎, and then a zero sequence admittance phase is calculated, that is, the zero sequence admittance angle. If the zero sequence admittance phase is in the range of (90°,180°), then the line is determined to be a faulty line, and the above method is used to verify that the line L3 is a faulty line.

The position of the ground faulty point in the line L3 is changed and the negative sequence impedance angles at different fault positions are obtained. The results are as shown in Table 1.

TABLE 1
Simulation results with two different fault positions

| Fault Positions | | L3 being a faulty line | L3 being a normal line |
|---|---|---|---|
| l_{f1}/km | l_{f2}/km | θₖ | θₛₑₜ |
| 0.1 | 4 | −92.7180 | 22.9152 |
| 0.1 | 8 | −92.7167 | 22.9144 |
| 4 | 8 | −92.7193 | 22.91786 |
| 4 | 12 | −92.7185 | 22.91729 |

According to Table 1, the negative sequence measurement impedance angle of the faulty line remains substantially unchanged at around −92.7° depending on the fault position (represented as the distance between the faulty point and the bus bar), indicating that the negative sequence measurement impedance angle of the faulty line is not affected by the change of the fault position. The impedance angle difference Δθ between the negative sequence measurement impedance angle of the faulty line and the negative sequence measurement impedance angle of the normal line, that is, the normal negative sequence impedance angle θₛₑₜ, remains at around −115.6°, which is significant and is in the impedance angle difference interval C_{θ}. By obtaining the negative sequence measurement impedance angle of the line, the faulty line can be accurately identified and protected, without being affected by the position of the faulty point.

By changing the transition resistance in the line, the negative sequence measurement impedance angles are obtained with different transition resistances. The results are as shown in Table 2.

TABLE 2
Simulation results with different transition resistances

| Transition resistance | L3 being a faulty line | L3 being a normal line |
|---|---|---|
| R/Ω | θₖ | θₛₑₜ |
| 1 | −92.7226 | 22.7213 |
| 10 | −92.7232 | 22.7286 |
| 100 | −92.7142 | 22.7174 |
| 500 | −92.5438 | 22.5459 |
| 1000 | −92.1994 | 22.1996 |

According to Table 2, as the transition resistance increases, the negative sequence measurement impedance angle of the faulty line remains substantially unchanged at around −92.7°, that is, the negative sequence measurement impedance angle of the faulty line does not change with the transition resistance. And the impedance angle difference Δθ between the negative sequence measurement impedance angle of the faulty line and the normal negative sequence measurement impedance angle of the normal line remains at around −115°, which is significant and is in the impedance angle difference interval C_{θ}. By obtaining the negative sequence measurement impedance angle, the faulty line can be accurately identified and protected, which is not affected by the transition resistance and is capable of effectively positioning the faulty line among multiple lines with different transition resistances, having a wide range of applicability.

In the present disclosure, the negative sequence measurement impedance or the negative sequence measurement admittance can be calculated by obtaining the beginning-end negative sequence current and the negative sequence voltage of the line, and the negative sequence measurement impedance angle or the negative sequence measurement admittance angle can be further obtained, which can be used to identify and judge the faulty line and form protection. The complex fault protection method of the present disclosure can provide protection for complex fault situations in a single return line with two-point out-of-phase ground, and only requires the negative sequence information of the line to identify the faulty line; moreover, the information acquisition and communication volume are small, and the requirements for equipment synchronization are low, thus, the method can be easily applied. At the same time, the method can respond to the change of the two-point ground position, and is not affected by factors such as the fault position and the transition resistance. Furthermore, the method can also be effectively applied when two phases are grounded at the same point, and has a strong anti-interference ability and a high stability, applicability, and sensitivity.

The present disclosure further provides a complex fault protection system for a single return line of an arc suppression coil ground system, including an acquisition module and a judgement module.

The acquisition module is configured to to obtain a negative sequence measurement impedance angle or a negative sequence measurement admittance angle of a line in the arc suppression coil ground system.

The judgment module is configured to determine whether a ground fault occurs in a corresponding line according to the negative sequence measurement impedance angle or the negative sequence measurement admittance angle.

The complex fault protection system of this embodiment is based on the same inventive concept as the complex fault protection method described above, and can be understood with reference to the description above, which is not repeated hereinafter.

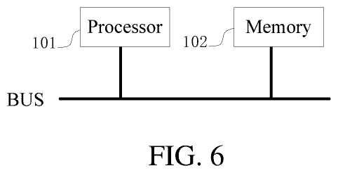

As shown in FIG. 6, the present disclosure further provides a computer device, including a processor 101 and a memory 102 signally connected to the processor 101 by a bus. The memory 102 stores at least one instruction or at least one program, which, when loaded by the processor 101, implements the complex fault protection method as described above. The memory 102 can be used to store software programs and modules, and the processor 101 executes various functional applications by running the software programs and modules stored in the memory 102. The memory 102 mainly includes a program storage area and a data storage area. The program storage area can store operating systems and application programs required for performing various functions, etc. The data storage area can store data created based on the usage of the computer device. In addition, the memory 102 may include a high-speed random access memory, as well as a non-volatile memory such as at least one disk storage device, a flash memory device, or other volatile solid-state storage devices. Correspondingly, the memory 102 may also include a memory controller to provide the processor 101 with access to the memory 102.

The method embodiments provided in the present disclosure can be executed in computer terminals, servers, or similar computing devices, that is, the above-mentioned computer device may be a computer terminal, a server, or any other similar computing device. The internal structure of the computer device may include but is not limited to: a processor, a network interface, and a memory. The processor, the network interface, and the memory within the computer device can be connected through a bus or other means.

The processor 101 (also known as the Central Processing Unit (CPU)) is the computing core and control core of the computer device. The optional network interfaces can include standard wired interfaces, wireless interfaces (such as WI-FI interfaces and mobile communication interfaces). The memory 102 is used to store programs and data. It can be understood that the memory 102 here can be a high-speed RAM storage device or a non-volatile memory device, such as at least one disk storage device. Optionally, the memory 102 can also be at least one storage device located far away from the processor 101. The memory 102 provides storage space that stores the operating system of the computer device, which may include but is not limited to: a Windows system (an operating system), a Linux system (an operating system), an Android system (a mobile operating system), an IOS system (a mobile operating system), etc. Moreover, the storage space also stores one or more instructions suitable for being loaded and executed by the processor 101, which may be one or more computer programs (including program codes). In the embodiments described in the present disclosure, the processor 101 loads and executes one or more instructions stored in the memory 102 to implement the complex fault protection method described in the above method embodiments.

The present disclosure also provides a computer-readable storage medium on which at least one instruction or at least one program is stored. When the at least one instruction or the at least one program is loaded by the processor 101, the complex fault protection method for a single return line of an arc suppression coil ground system as described above is implemented. The above-mentioned computer-readable storage medium carries one or more programs, and when the above-mentioned one or more programs are executed, the complex fault protection method according to the disclosed embodiments is implemented.

According to the disclosed embodiments, the computer-readable storage medium may be a non-volatile computer-readable storage medium, such as but not limited to: a portable computer disk, a hard drive, a random access memory (RAM), a read-only memory (ROM), an erasable programmable read-only memory (EPROM or flash memory), a portable compact disk read-only memory (CD-ROM), an optical storage device, a magnetic storage device, or any suitable combination thereof. In the present disclosure, the computer-readable storage medium may be any tangible medium that can contain or store a program, the program may be an instruction execution system, apparatus or device or used in combination therewith.

In the description of the present disclosure, it should be understood that directional words such as “front, back, up, down, left, right”, “horizontal, vertical, horizontal”, and “top, bottom” usually indicate directional or positional relationships based on the directional or positional relationships shown in the accompanying drawings. This is only for the convenience of describing the present disclosure and simplifying the description. Without contrary explanation, these directional words do not indicate or imply that the device or component referred to must have a specific orientation or be constructed and operated in a specific orientation, and therefore cannot be understood as limiting the scope of protection of the present disclosure.

It is understandable that the above-mentioned technical features may be used in any combination without limitation. The above descriptions are only the embodiments of the present disclosure, which do not limit the scope of the present disclosure. Any equivalent structure or equivalent process transformation made by using the content of the description and drawings of the present disclosure, or directly or indirectly applied to other related technologies in the same way, all fields are included in the scope of patent protection of the present disclosure.

What is claimed is:

1. A complex fault protection method for a single return line of an arc suppression coil ground system, wherein whether a ground fault occurs in a corresponding line or not is determined according to a negative sequence measurement impedance angle or a negative sequence measurement admittance angle of the corresponding line of the arc suppression coil ground system.

2. The complex fault protection method according to claim 1, further comprising the following steps:
obtaining a negative sequence impedance angle of each line when the arc suppression coil ground system is in normal operation, wherein the negative sequence impedance angle is marked as θₛₑₜ;
obtaining the negative sequence measurement impedance angle θₖ of a line potentially having a ground fault;
calculating an impedance angle difference between the negative sequence measurement impedance angle θₖ and the normal negative sequence impedance angle θₛₑₜ, wherein the impedance angle difference is marked as Δθ;
determining whether the impedance angle difference Δθ is in a preset impedance angle difference interval, when the impedance angle difference Δθ is in the preset impedance angle difference interval, it is determined that the line has a ground fault, otherwise, it is determined that the line has no ground faults; or,
obtaining a negative sequence admittance angle of each line when the arc suppression coil ground system is in normal operation, wherein the normal negative sequence admittance angle is marked as φₛₑₜ;
obtaining the negative sequence measurement admittance angle φₖ of the line potentially having a ground fault;
calculating an admittance angle difference between the negative sequence measurement admittance angle φₖ and the normal negative sequence admittance angle φₛₑₜ, wherein the admittance angle difference is marked as Δφ;
determining whether the admittance angle difference Δφ is in a preset admittance angle difference interval; when the admittance angle difference Δφ is in the preset admittance angle difference interval, it is determined that the line has a ground fault; otherwise, it is determined that the line no ground faults.

3. The complex fault protection method according to claim 2, wherein the line potentially having a ground fault is determined by the following steps:
obtaining a negative sequence current setting value İₛₑₜ of the arc suppression coil ground system;
obtaining a beginning-end negative sequence current İ_{L(2)} of each line; and
determining whether the beginning-end negative sequence current İ_{L(2)} is greater than the negative sequence current setting value İₛₑₜ; when the beginning-end negative sequence current İ_{L(2)} is greater than the negative sequence current setting value İₛₑₜ, it is determined that the line potentially has a ground fault; otherwise, it is determined that the line operates normally.

4. The complex fault protection method according to claim 3, wherein the negative sequence measurement impedance angle θₖ of the line potentially having a ground fault is calculated according to the following steps:
obtaining a negative sequence voltage \dot{U}_{L(2)} of the line potentially having a ground fault;
calculating the negative sequence measurement impedance angle θₖ according to the following formula:
$${θ}_{k} = arg \frac{{\dot{U}}_{L ( 2 )}}{{\dot{I}}_{L ( 2 )}} ;$$
calculating the negative sequence measurement admittance angle φₖ of the line potentially having a ground fault according to the following steps:
obtaining the negative sequence voltage \dot{U}_{L(2)} of the line potentially having a ground fault; and
calculating the negative sequence measurement admittance angle φₖ according to the following formula:
$${φ}_{k} = - arg \frac{{\dot{U}}_{L ( 2 )}}{{\dot{I}}_{L ( 2 )}} .$$

5. The complex fault protection method according to claim 3, wherein the negative sequence current setting value is calculated according to the following formula:
$${\dot{I}}_{set} = {k}_{k} \vert {\dot{I}}_{k ( 2 )} \vert ;$$
wherein, \dot{k}ₖ represents a reliability coefficient and İₖ₍₂₎ represents the negative sequence current generated on the faulty line when other feeders have single-phase ground faults.

6. The complex fault protection method according to claim 2, wherein the impedance angle difference interval C_{θ}=[−180°, −90° ], and the admittance angle difference interval C_{φ}=[90°, 180° ].

7. (canceled)

8. A computer device comprising a processor and a memory signally connected to the processor, wherein the memory stores at least one instruction or at least one program which, when being loaded by the processor, implements the complex fault protection method for a single return line of an arc suppression coil ground system according to claim 1.

9. A non-transitory computer-readable storage medium storing at least one instruction or at least one program, wherein when the at least one instruction or the at least one program is loaded by a processor, the complex fault protection method for a single return line of an arc suppression coil ground system according to claim 1 is implemented.

10. The complex fault protection method according to claim 3, wherein the impedance angle difference interval C_{θ}=[−180°, −90° ], and the admittance angle difference interval C_{φ}, [90° , 180° ].

11. The complex fault protection method according to claim 4, wherein the impedance angle difference interval C_{θ}=[−180°−90° ], and the admittance angle difference interval C_{φ}, [90°, 180° ].

12. The complex fault protection method according to claim 5 wherein the impedance angle difference interval C_{θ}=[−180°, −90° ], and the admittance angle difference interval C_{φ}, [90°, 180° ].

13. A computer device comprising a processor and a memory signally connected to the processor, wherein the memory stores at least one instruction or at least one program which, when being loaded by the processor, implements the complex fault protection method for a single return line of an arc suppression coil ground system according to claim 2.

14. A computer device comprising a processor and a memory signally connected to the processor, wherein the memory stores at least one instruction or at least one program which, when being loaded by the processor, implements the complex fault protection method for a single return line of an arc suppression coil ground system according to claim 3.

15. A computer device comprising a processor and a memory signally connected to the processor, wherein the memory stores at least one instruction or at least one program which, when being loaded by the processor, implements the complex fault protection method for a single return line of an arc suppression coil ground system according to claim 4.

16. A computer device comprising a processor and a memory signally connected to the processor, wherein the memory stores at least one instruction or at least one program which, when being loaded by the processor, implements the complex fault protection method for a single return line of an arc suppression coil ground system according to claim 5.

17. A computer device comprising a processor and a memory signally connected to the processor, wherein the memory stores at least one instruction or at least one program which, when being loaded by the processor, implements the complex fault protection method for a single return line of an arc suppression coil ground system according to claim 6.

18. A non-transitory computer-readable storage medium storing at least one instruction or at least one program, wherein when the at least one instruction or the at least one program is loaded by a processor, the complex fault protection method for a single return line of an arc suppression coil ground system according to claim 2 is implemented.

19. A non-transitory computer-readable storage medium storing at least one instruction or at least one program, wherein when the at least one instruction or the at least one program is loaded by a processor, the complex fault protection method for a single return line of an arc suppression coil ground system according to claim 3 is implemented.

20. A non-transitory computer-readable storage medium storing at least one instruction or at least one program, wherein when the at least one instruction or the at least one program is loaded by a processor, the complex fault protection method for a single return line of an arc suppression coil ground system according to claim 4 is implemented.

21. A non-transitory computer-readable storage medium storing at least one instruction or at least one program, wherein when the at least one instruction or the at least one program is loaded by a processor, the complex fault protection method for a single return line of an arc suppression coil ground system according to claim 5 is implemented.
